(19) United States
(12) Patent Application Publication
(10) Pub. No.: US 2006/0145315 A1
(43) Pub. Date: Jul. 6, 2006

(54) Flexible substrate for package

(75) Inventors: Hung-Che Shen, Kaohsiung City (TW); Hung-Hsin Liu, Tainan City (TW); Geng-Shin Shen, Tainan City (TW)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: ChipMos Technologies Inc.

(21) Appl. No.: 11/250,989

(22) Filed: Oct. 13, 2005

(30) Foreign Application Priority Data
Dec. 31, 2004 (TW) 093141897

(51) Int. Cl. H01L 23/495

(52) U.S. Cl. 257/668

(57) ABSTRACT

The invention provides a flexible substrate for package of a semiconductor die. The flexible substrate includes a flexible insulating film, a plurality of first leads substantially formed on the flexible insulating film, and at least one loop-shaped second lead substantially formed on the flexible insulating film. The at least one second lead is partially disposed at a corner of a device hole of the flexible film, and is designed as being capable of preventing from fracture induced during the package of the semiconductor die. Preferably, the portion of each of the at least one second lead, to be overlapped over the semiconductor die, exhibits an L-shape, a U-shape or a Y-shape.

### BACKGROUND OF THE INVENTION

1. Field of the Invention

This present invention relates to a flexible substrate for package of a semiconductor die, and more particularly, to a flexible substrate with capability of preventing leads thereof from fracture induced during package of a semiconductor die.

2. Description of the Prior Art

In the field of package of integrated circuit dies, tape carrier package (TCP) is one of the popular methods. The TCP employs a flexible substrate with a device hole and a plurality of leads as a carrier for the packed die.

Referring to FIG. 1 and FIG. 2, FIG. 1 is a cross-sectional view of a conventional TCP structure 2, and FIG. 2 is a top view of the conventional TCP structure 2 shown in FIG. 1. The manufacture regarding the conventional TCP structure 2 shown in FIG. 1 and FIG. 2 is described as follows.

First, a semiconductor die 10 having bumps 12, such as gold bumps, is prepared. Then, the semiconductor die 10 is disposed at a device hole 24 of a tape. The flexible substrate includes an insulating film 22, made of polyimide or the like, as the substrate of the tape and a patterned conductor deposited on an adhesive layer thereon. Usually, a plurality of sprocket holes 28 are formed on the two sides of the insulating film 22 for transportation and orientation during package of the semiconductor die 10. The patterned conductor forms inner leads 26 and outer leads (not shown). Next, through an inner lead bonding (ILB) process, the gold bumps 12 on the semiconductor die 10 are bonded to the inner leads 26 of the flexible substrate. When the gold of the gold bumps 12 and the tin of the inner leads 26 form a eutectic alloy, the ILB process is completed. Since the semiconductor die 10 is held by the inner leads 26 after the ILB process, a sealing liquid resin 14 is applied onto a predetermined area of the semiconductor die 100. Then, the liquid resin 14 is cured so as to seal the junction portion of the semiconductor die 10 and the inner leads 26. The curing of the resin 14 is carried out at about 100 degree Centigrade or higher for several hours. After the liquid resin 14 is cured, the resulted TCP structure 2 is marked and is then subjected to a final test. Thereafter, the real-shaped tape with packed dies is directly shipped without any necessity of post-process, or is only cut into pieces to be shipped as slide carriers.

The TCP manufacture described above is most suitable for package of the semiconductor device has multi-connection terminals and needs a compact package size. Thus, at present, such TCPs are the most widely utilized carrier packages for LCD drivers.

However, as shown in FIG. 1, during the inner lead bonding process of bonding the gold bumps 12 with the inner leads 26, the inner leads easily bend and plastically deform due to applied heat and press, and thus, the stress concentrates preferentially at the outermost inner leads. It is noted that numeral notation 25 in FIG. 1 represents a broken position of the inner lead 26. Without strong support, the outermost inner leads 26 are easily broken so that the electrical connections of the packed die through the broken leads are broken off.

Accordingly, a scope of the invention is to provide a flexible substrate for package of a semiconductor die, and particularly, the flexible substrate according to the invention has capability of preventing leads thereof from breaking induced during the inner lead bonding process mentioned above.

### SUMMARY OF THE INVENTION

To achieve the objective and to solve the shortcomings discussed above, the invention provides a flexible substrate for package which is capable of preventing leads thereof from breaking induced during package.

A flexible substrate, according to a preferred embodiment of the invention, includes a flexible insulating film, a plurality of first leads, and at least one loop-shaped second lead. In this embodiment, the flexible substrate is used for tape carrier package, and the flexible insulating film has a device hole thereon. The plurality of first leads are substantially formed on the flexible insulating film, and they partially protrude to the device hole. The at least one second lead is substantially formed on the flexible insulating film, and it also partially protrudes to the device hole.

According to another preferred embodiment of the invention, the flexible substrate includes a flexible insulating film, a plurality of first leads, and at least one Y-shaped second lead. The plurality of first leads and the at least one Y-shaped second lead are substantially formed on the flexible insulating film, and the at least one second lead is arranged at either or both of two sides of the whole of the first leads.

A tape carrier package (TCP) structure, according to a preferred embodiment of the invention, includes a flexible substrate, a semiconductor die, and a resin.

The flexible substrate includes a flexible insulating film, a plurality of first leads, and at least one loop-shaped second lead. The plurality of first leads and the at least one second lead are formed on the flexible insulating film. The semiconductor die has an active surface and a plurality of bumps formed on the active surface; each of the bumps is bonded to one of the first leads and the at least one second lead. The resin is coated on the flexible insulating film, so as to cover and seal the first leads, the at least one second lead, and the bumps.

The flexible substrate, according to the invention, for package improves the shape of the leads thereon, so that the leads, which are located in the locations under stress concentration such as the corners of the flexible insulating film, can lower the stress concentration factor because of its shape. Therefore, the breaking of the lead and the resulted electricity disconnection can be avoided, thus increasing the reliability of package.

The advantage and spirit of the invention may be understood by the following recitations together with the appended drawings.

### BRIEF DESCRIPTION OF THE APPENDED DRAWINGS

FIG. 1 is a cross-sectional view of a conventional TCP structure 2.

FIG. 2 is a top view of the conventional TCP structure 2 in FIG. 1.

FIG. 3 is a schematic diagram illustrating a flexible substrate according to the first preferred embodiment of the invention.

FIG. 4 is a schematic diagram illustrating a flexible substrate according to the second preferred embodiment of the invention.

FIG. 5 is a schematic diagram illustrating a flexible substrate according to the third preferred embodiment of the invention.

FIG. 6 is a schematic diagram illustrating other available shapes of the second lead of the flexible substrate according to the invention.

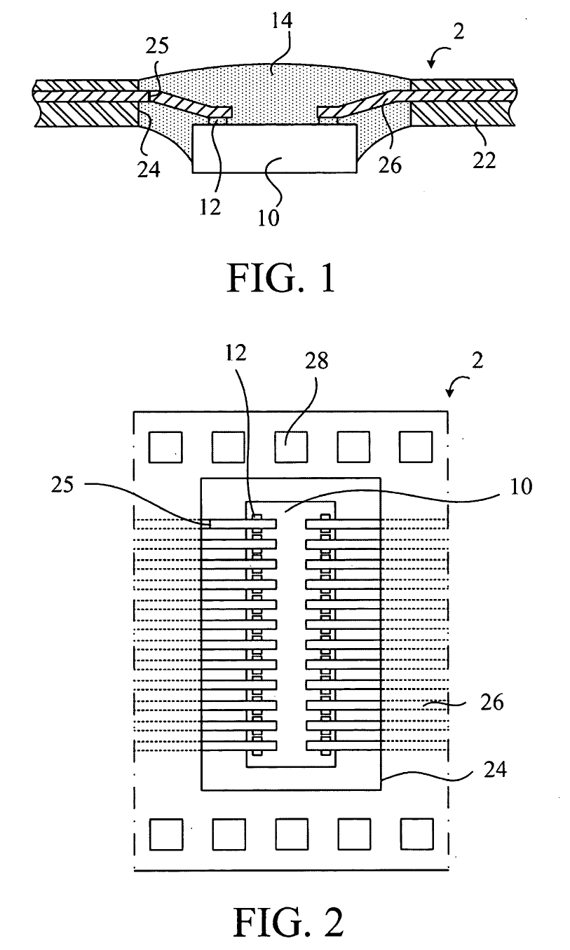

### DETAILED DESCRIPTION OF THE INVENTION

The invention provides a flexible substrate for package of a semiconductor die. The flexible substrate, according to invention, essentially includes a flexible insulating film, a plurality of first leads, and at least one loop-shaped second lead. Each of the at least one second lead is divided into a head section and a tail section, and the width of the head section is less than or equal to that of the tail section. The flexible insulating film has a device hole thereon. The plurality of first leads are substantially formed on the flexible insulating film, and partially protrude to the device hole. The at least one second lead is substantially formed on the flexible insulating film, and partially protrudes to the device hole. By describing several preferred embodiment thoroughly, the spirit and characteristics of the invention will be pointed out.

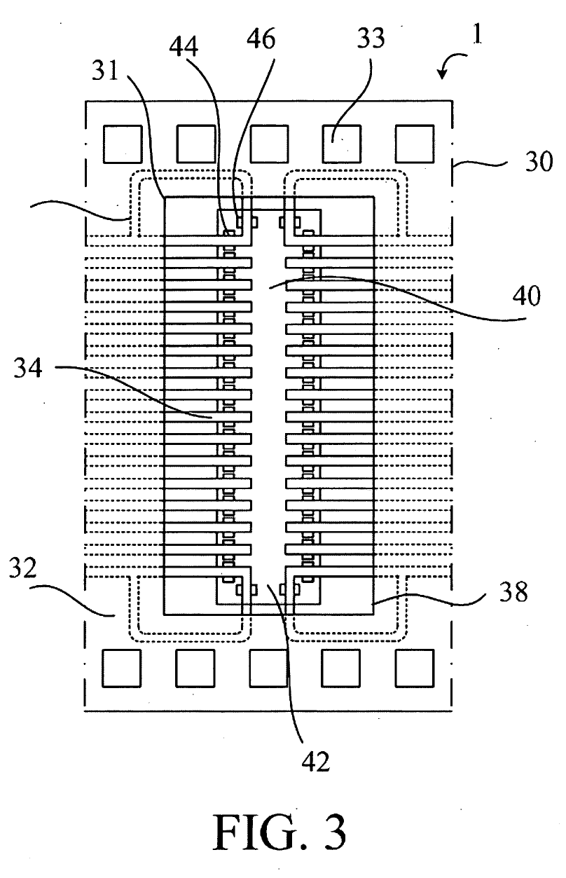

Please refer to FIG. 3, FIG. 3 is a schematic diagram illustrating a flexible substrate 30 according to the first preferred embodiment of the invention. A TCP structure 1, which employs the flexible substrate 30 according to the first preferred embodiment of the invention, is also shown in FIG. 3. The TCP substrate 1 in FIG. 3 includes the flexible substrate 30, a semiconductor die 40, and a resin (not shown).

As shown in FIG. 3, the flexible substrate 30 includes a flexible insulating film 32, a plurality of first leads 34, and at least one loop-shaped second lead 36. In this case in FIG. 3, the flexible substrate 30 has four second leads 36. The flexible insulating film 32 is made of polyimide, polyester or the like. A device hole 38 passes vertically through the flexible insulating film 32. The device hole 38 is roughly rectangular and has four corners 31. With the device hole 38, the flexible insulating film 32 cannot be pressed by a thermo-compression head during an inner lead bonding process. There are a plurality of equidistant sprocket holes 33 formed on the two sides of the flexible insulating film 32 for transportation and orientation during the package of the semiconductor die 40.

As shown in FIG. 3, the plurality of strip-shaped first leads 34 and the second leads 36 are substantially formed on the flexible insulating film 32, and partially protrude to the device hole 38. Preferably, the portions of the first leads 34 on the flexible insulating film 32 and the portions of the second leads 36 on the flexible insulating film 32 are covered by a protection layer (not shown), such as a solder mask or a cover film. In this case in FIG. 3, the first leads 34 are arranged along the two longer sides of the device hole 38. Otherwise, the first leads 34 can be arranged along each of the four sides of the device hole 38, if needed. The second leads 36 are arranged at specific locations of the flexible insulating film 32 where the stress preferentially concentrates during the inner lead bonding process. Usually, the specific location refer to the locations near the two sides of the whole of the first leads.

The semiconductor die 40 has an active surface 42 and a plurality of bumps 44 formed on the active surface 42. Each of the bumps 44 is bonded to one of the first leads 34 and the second leads 36. Usually, after the leads 34 and 36 are bonded between the flexible substrate 30 and the semiconductor die 40, the resin is coated and cured on the device hole 38, so as to cover and seal the first leads 34 and the second leads 36 in the device hole 38, and the bumps 44. After the resulted TCP structure is appropriately cut, a chip with wafer-level chip size package is completed.

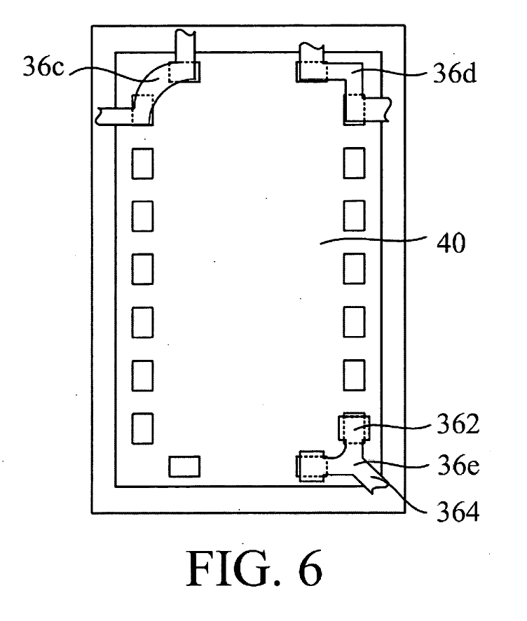

As shown in FIG. 3, in the first preferred embodiment, the second leads 36 are disposed at the corners 31 of the device hole 38, and a portion of each of the second leads 36 overlapped over the semiconductor die 40 exhibits an L-shape. In this case, the L-shaped portion of the second lead 36 directs to the center of the device hole 38, and otherwise, it can also be designed as directing to the edge of the device hole 38, as the second lead 36d shown in FIG. 6. These second leads 36 with desired shape has lower stress concentration factor, and thus can reduce the fracture possibility thereof induced during the package of the semiconductor die 40. Moreover, other than those bumps 44, the active surface 42 of the semiconductor die 40 thereon can further form at least one dummy bump 46 to assist in connecting and supporting the second leads 36. Therefore, the second leads 36 are less prone to be broken; even if one of the second leads 36 is partially broken, the electrical connection of the packed die through the broken lead is still remained.

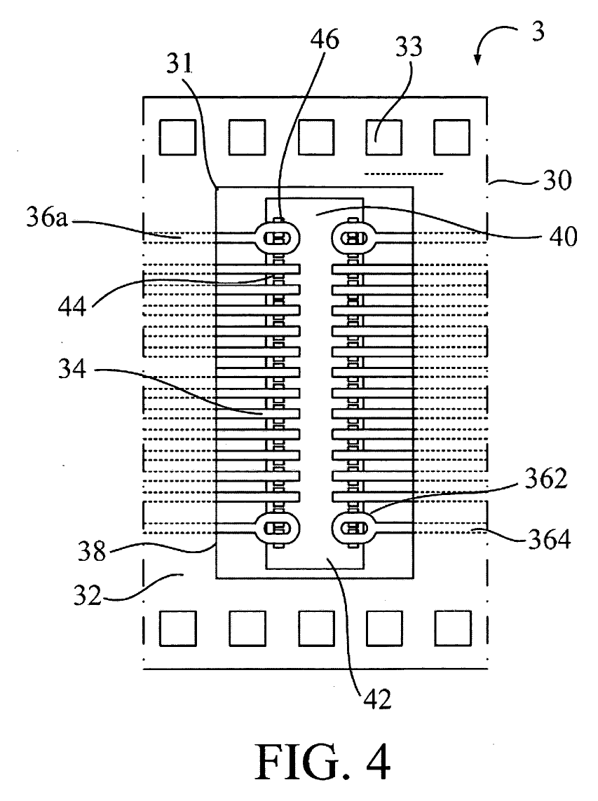

The invention does not limit the shape of the second leads 36. Please refer to FIG. 4; FIG. 4 is a schematic diagram illustrating a flexible substrate 30 according to the second preferred embodiment of the invention. A TCP structure 3, which employs the flexible substrate 30 according to the second preferred embodiment of the invention, is also shown in FIG. 4. The TCP structure 3 in FIG. 4 includes the flexible substrate 30, a semiconductor die 40, and a resin (not shown). As shown in FIG. 4, the flexible substrate 30 includes a flexible insulating film 32 with a device hole 38 thereon, a plurality of strip-shaped first leads 34, and a plurality of loop-shaped second leads 36a.

As shown in FIG. 4, the plurality of first leads 34 and the second leads 36a are substantially formed on the flexible insulating film 32 and partially protrude to the device hole 38. Each of the second leads 36a is divided into a head section 362 and a tail section 364, and the width of the head section 362 is less than or equal to the that of the tail section 364. Each of the first leads 34 has a suspended end, protruding to the device hole 38, to be bonded to one of the bumps 44 on the active surface 42 of the semiconductor die 40 by an inner lead bonding process. The resin is coated so as to cover and seal the first leads 34 and the second leads 36a in the device hole 38, and the bumps 44. It is noted that, in the second preferred embodiment, a portion of each of the second leads 36a overlapped over the semiconductor die 40 exhibits a U-shape for protecting the second leads 36a from stress concentration induced during the package of the die 40. Furthermore, the second leads 36a are disposed at the locations of the flexible insulating film 32 where the stress preferentially concentrates during the inner lead bonding process, such as the corners 31 of the device hole 38, to reduce the fracture possibility thereof induced during the inner lead bonding process. In the inner lead bonding process, each of the second leads 36a can be bonded to one bump 44 and one dummy bump 46 on the semiconductor die 40.

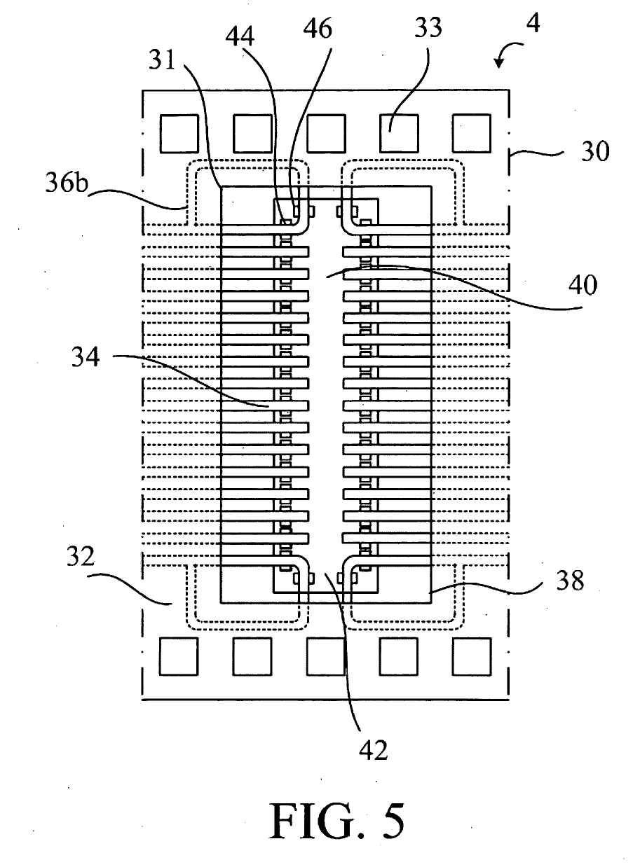

Please refer to FIG. 5; FIG. 5 is a schematic diagram illustrating a flexible substrate 30 according to the third preferred embodiment of the invention. A TCP structure 4, which employs the flexible substrate 30 according to the third preferred embodiment of the invention, is also shown in FIG. 5. It is noted that, in the third preferred embodiment of the invention, each of a portion of the second leads 36b suspended in the device hole 38 exhibits an arc shape. Each of the second leads 36b is bonded to one bump 44 and one dummy bump 46 formed on the semiconductor die 40. In this case, the arc-shaped portion of the second lead 36b directs to the center of the device hole 38, and otherwise, it can also be designed as directing to the edge of the device hole 38, as the second lead 36c shown in FIG. 6.

The flexible substrate according to the invention does not limit in application of the tape carrier package, and it can also be applied in chip-on-film (COF) package. It is noted that the at least one second lead is arranged at two sides of the whole of the first leads, and is bonded to a bump and a dummy bump on the semiconductor die. It is also noted that a portion of each of the at least on second lead overlapped over the semiconductor die exhibits an L shape, a U shape or an arc shape.

In another preferred embodiment, the flexible substrate according to the invention includes an flexible insulating film, a plurality of first leads formed on the flexible insulating film, and at least one second lead with a Y-shaped portion as the second lead 36e shown in FIG. 6. The at least one second lead is formed on the flexible insulating film, and arranged at two sides of the whole of the first leads. Each of the at least one second lead is bonded to a bump and a dummy bump. Each of the at least one second lead is divided into a head section and a tail second, and the width of the head section is less than or equal to that of the tail section.

Please refer to FIG. 6; FIG. 6 is a schematic diagram illustrating other available shapes of the second lead of the flexible substrate according to the invention. As shown in FIG. 6, the portion of the second lead 36c overlapped over the semiconductor die 40 exhibits an arc shape, and the arc-shaped portion of the second lead 36c directs to the edge of the semiconductor die 40. As shown in FIG. 6, the portion of the second lead 36d overlapped over the semiconductor die 40 exhibits an L shape, and the L-shaped portion of the second lead 36d directs to the edge of the semiconductor die 40. As shown in FIG. 6, the second lead 36e is via a Y-shaped portion thereof bonded to the semiconductor die 40. The second lead 36e with the Y-shaped portion can be divided into a head section 362 and a tail section 364, and the width of the head section 362 is less than or equal to that of the tail section 364.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A flexible substrate for package of a semiconductor die, said flexible substrate comprising:
a flexible insulating film;
a plurality of first leads being substantially formed on the flexible insulating film; and
at least one loop-shaped second lead being substantially formed on the flexible insulating film.

2. The flexible substrate of claim 1, wherein each of the at least one second lead is divided into a head section and a tail section, and the width of the head section is less than or equal to that of the tail section.

3. The flexible substrate of claim 1, wherein the plurality of first leads are strip-shaped.

4. The flexible substrate of claim 1, wherein the at least one second lead is arranged at either or both of the two sides the whole of the first leads.

5. The flexible substrate of claim 1, wherein a portion of each of the at least one second lead, to be overlapped over the semiconductor die, exhibits an L-shape.

6. The flexible substrate of claim 1, wherein a portion of each of the at least one second lead, to be overlapped over the semiconductor die, exhibits a U-shape.

7. The flexible substrate of claim 1, wherein a portion of each of the at least one second lead, to be overlapped over the semiconductor die, exhibits an arc shape.

8. The flexible substrate of claim 1, further comprising a protection layer covering the portions of the first leads on the flexible insulating film and the portion of the at least one second lead on the flexible insulating film.

9. The flexible substrate of claim 1, wherein the semiconductor die is packaged via said flexible substrate by a tape carrier package process, the flexible insulating film has a device hole, and the at least one second lead is partially disposed at a corner of the device hole.

10. A flexible substrate for package of a semiconductor die, said flexible substrate comprising:
a flexible insulating film;
a plurality of first leads being substantially formed on the flexible insulating film; and
at least one Y-shaped second lead being substantially formed on the flexible insulating film.

11. The flexible substrate of claim 10, wherein each of the at least one Y-shaped second lead is divided into a head section and a tail section, and the width of the head section is less than or equal to that of the tail section.

12. The flexible substrate of claim 10, wherein the at least one second lead is arranged at either or both of the two sides the whole of the first leads.

13. The flexible substrate of claim 10, wherein the semiconductor die is packaged via said flexible substrate by a tape carrier package process, the flexible insulating film has a device hole, and the at least one second lead is partially disposed at a corner of the device hole.
